(19) United States
(12) Patent Application Publication
(10) Pub. No.: US 2024/0373670 A1
(43) Pub. Date: Nov. 7, 2024

(54) DISPLAY DEVICE AND METHOD OF MANUFACTURING THE SAME

(71) Applicant: Samsung Display Co., LTD., Yongin-si (KR)

(72) Inventors: Jeong Weon SEO, Yongin-si (KR); Jun Young LEE, Yongin-si (KR); Jun Woo YOU, Yongin-si (KR); Sung Woon IM, Yongin-si (KR)

(21) Appl. No.: 18/506,635

(22) Filed: Nov. 10, 2023

(30) Foreign Application Priority Data
May 4, 2023 (KR) 10-2023-0058507

(51) Int. Cl. H10K 59/12; H10K 59/126; H10K 59/40; H10K 59/80; H10K 59/88; H10K 71/40

(52) U.S. Cl. CPC H10K 59/1201; H10K 59/126; H10K 59/40; H10K 59/8791; H10K 59/88; H10K 71/40; H10K 2102/361

(57) ABSTRACT

In a method of manufacturing a display device, the method includes: forming a frame comprising openings by applying a first resin to a surface of a mother substrate and curing the first resin; forming protective members by applying a second resin to the openings of the frame and curing the second resin; and cutting the mother substrate along an area between the protective members after removing the frame, wherein the second resin comprises a different material from the first resin.

### CROSS-REFERENCE TO RELATED APPLICATION

The present application claims priority to and the benefit of Korean Patent Application No. 10-2023-0058507, filed on May 4, 2023, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

Display devices are becoming increasingly important with the development of multimedia. The display devices include liquid crystal displays (LCDs) and organic light emitting displays (OLEDs).

A display device may include a protective member having functions such as heat dissipation and buffering on a lower surface of a display panel to protect itself from heat generated from a light emitting element or a driving chip driving the light emitting element and from external impact.

Such a protective member may include a plurality of different functional layers performing their respective functions such as heat dissipation and buffering, but may also include a single functional layer that can perform all of the above functions.

The above information disclosed in this Background section is only for enhancement of understanding of the background and therefore the information discussed in this Background section does not necessarily constitute prior art.

### SUMMARY

Aspects of some embodiments of the present disclosure include a display device including a protective member having a heat dissipation function, an electromagnetic wave shielding function, a light blocking function, and a shock absorbing function.

Aspects of some embodiments of the present disclosure may also include a method of manufacturing a display device with relatively improved yield of a protective member forming process.

However, aspects of embodiments of the present disclosure are not restricted to those specifically set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, in a method of manufacturing a display device, the method includes, forming a frame including openings by applying a first resin to a surface of a mother substrate and curing the first resin, forming protective members by applying a second resin to the openings of the frame and curing the second resin, and cutting the mother substrate along an area between the protective members after removing the frame, wherein the second resin includes a different material from the first resin.

According to some embodiments, in the forming of the protective members, the protective members are surrounded by the frame and located in the openings.

According to some embodiments, in the forming of the protective members, a thickness of the second resin before being cured in the openings is smaller than or equal to a thickness of the frame.

According to some embodiments, a thickness of the second resin after being cured in the openings is 40% to 60% of the thickness of the second resin before being cured.

1 According to some embodiments, a thickness of each protective member is 100 to 300 μm.

According to some embodiments, the second resin comprises at least one of a binder, first fillers, second fillers, light blocking materials, or foaming agents.

According to some embodiments, the first fillers comprise at least one of a carbon-based material and a ceramic-based material, or the second fillers comprise at least one of a carbon-based material or a metal-based material.

According to some embodiments, the light blocking materials comprise at least one of carbon black, black pigment, or black dye.

According to some embodiments, the binder comprises at least one of acrylic resin, urethane resin, silicone resin, or rubber resin.

According to some embodiments, an elongation rate of the frame is 200% or more.

According to some embodiments, in the forming of the frame, the first resin is cured through thermal curing or natural curing.

According to some embodiments, the second resin has a viscosity of 10,000 to 50,000 cPs.

According to some embodiments, in the removing of the frame, the protective members comprise removal marks formed on side surfaces thereof as a result of removing the frame.

According to some embodiments, in the cutting of the mother substrate, a dummy is further between the protective members, and the mother substrate is cut along an area between the dummy and each of the protective members.

According to some embodiments, in the forming of the protective members, the second resin is applied into the openings through a screen printing method using a blade.

According to some embodiments, the method further comprises forming display layers on the other surface located opposite the surface of the mother substrate.

According to some embodiments of the present disclosure, a display device includes, a substrate, a display layer located on a surface of the substrate, and a protective member located on the other surface of the substrate and including a resin, wherein the protective member includes removal marks on side surfaces thereof, and the removal marks are formed as a result of removing a frame surrounding the protective member.

According to some embodiments, a thickness of the protective member is 100 to 300 μm.

According to some embodiments, the resin comprises at least one of a binder, first fillers, second fillers, light blocking materials, or foaming agents.

According to some embodiments, the first fillers comprise at least one of a carbon-based material or a ceramic-based material, and the second fillers comprise at least one of a carbon-based material or a metal-based material.

According to some embodiments, the light blocking materials comprise at least one of carbon black, black pigment, or black dye.

According to some embodiments, the binder comprises at least one of acrylic resin, urethane resin, silicone resin, or rubber resin.

According to some embodiments, an elongation rate of the frame is 200% or more.

A display device according to some embodiments of the present disclosure may include a protective member having a heat dissipation function, an electromagnetic wave shielding function, a light blocking function, and a shock absorbing function.

A method of manufacturing a display device according to some embodiments of the present disclosure can relatively improve the yield of a protective member forming process.

However, the characteristics of embodiments according to the present disclosure are not restricted to those specifically set forth herein. The above and other characteristics of embodiments according to the present disclosure will become more apparent to one of daily skill in the art to which the present disclosure pertains by referencing the claims.

### BRIEF DESCRIPTION OF THE DRAWINGS

These and/or other characteristics will become more apparent and more readily appreciated from the following description of the embodiments, taken in conjunction with the accompanying drawings in which:

FIG. 1 is a schematic perspective view of a display device according to some embodiments;

FIG. 2 is a schematic cross-sectional view of the display device according to some embodiments;

FIG. 3 is a schematic plan view of the display device according to some embodiments;

FIG. 4 is an equivalent circuit diagram of a pixel according to some embodiments;

FIG. 5 is a schematic cross-sectional view of a portion of a display panel according to some embodiments;

FIG. 6 is a schematic cross-sectional view of a portion of the display device according to some embodiments;

FIG. 7 schematically illustrates the state of a protective member before being cured according to some embodiments;

FIG. 8 schematically illustrates the state of the protective member after being cured according to some embodiments;

FIG. 9 is a flowchart illustrating a method of manufacturing a display device according to some embodiments;

FIG. 10 is a perspective view illustrating operation S100 of FIG. 9 according to some embodiments;

FIG. 11 is a perspective view illustrating operation S200 of FIG. 9 according to some embodiments;

FIG. 12 is a cross-sectional view taken along line X1-X1′ of FIG. 11 according to some embodiments;

FIG. 13 is a perspective view illustrating operation S300 of FIG. 9 according to some embodiments;

FIG. 14 is a cross-sectional view taken along line X2-X2′ of FIG. 13 according to some embodiments;

FIG. 15 is a perspective view illustrating operation S300 of FIG. 9 according to some embodiments;

FIG. 16 is a cross-sectional view taken along line X3-X3′ of FIG. 15 according to some embodiments;

FIG. 17 is a perspective view illustrating operation S400 of FIG. 9 according to some embodiments;

FIG. 18 is a cross-sectional view taken along line X4-X4′ of FIG. 17 according to some embodiments;

FIG. 19 is a perspective view illustrating an embodiment of operation S400 of FIG. 17 according to some embodiments;

FIG. 20 is a flowchart illustrating a method of manufacturing a display device according to some embodiments;

FIG. 21 is a perspective view illustrating operation S300_2 of FIG. 20 according to some embodiments;

FIG. 22 is a cross-sectional view taken along line X5-X5′ of FIG. 21 according to some embodiments;

FIG. 23 is a perspective view illustrating operation S400_2 of FIG. 20 according to some embodiments;

FIG. 24 is a perspective view illustrating operation S400_2 of FIG. 20 according to some embodiments; and

FIG. 25 is a cross-sectional view taken along line X6-X6′ of FIG. 24 according to some embodiments.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be more thorough and more complete, and will more fully convey the scope of embodiments according to the present invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

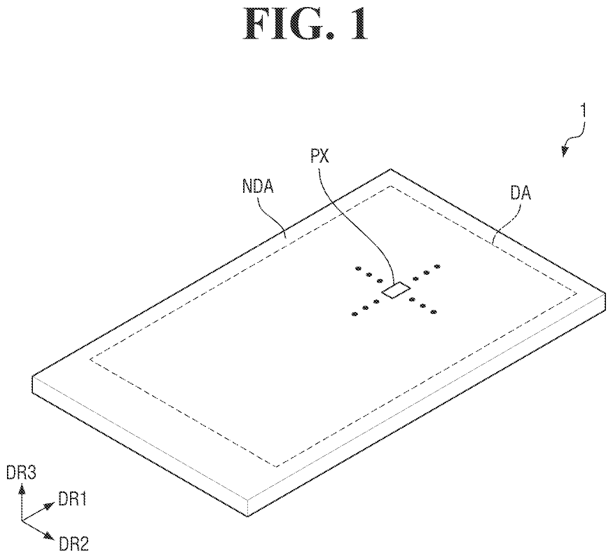

FIG. 1 is a schematic perspective view of a display device 1 according to some embodiments.

Referring to FIG. 1, the display device 1 may be applied to portable electronic devices such as mobile phones, smartphones, tablet personal computers (PCs), mobile communication terminals, electronic notebooks, electronic books, portable multimedia players (PMPs), navigation devices and ultra-mobile PCs (UMPCs), as well as to various products such as televisions, notebook computers, monitors, billboards, and Internet of things (IoT) devices. In addition, the display device 1 may be applied to wearable devices such as smart watches, watch phones, glass-like displays, and head-mounted displays (HMDs). In addition, the display device 1 may be applied to a dashboard of a vehicle, a center information display (CID) located on a center fascia or dashboard of a vehicle, a room mirror display replacing side mirrors of a vehicle, or a display screen located on the back of a front seat as an entertainment for a rear-seat passenger of a vehicle. Although an embodiment in which the display device 1 is a smartphone is illustrated in the drawings as an example, the present disclosure is not limited thereto.

The display device 1 may include a display area DA and a non-display area NDA located outside (e.g., in a periphery or outside a footprint of) the display area DA. The display area DA may display images through pixels PX located in the display area DA. Although FIG. 1 illustrates a single pixel PX, as a person having ordinary skill in the art would appreciate, the display area DA may include any suitable number of pixels PX according to the design and size of the display device 1. The non-display area NDA may be an area located outside the display area DA and not displaying images. The non-display area NDA may entirely surround the display area DA. A driver for providing electrical signals or power to the display area DA may be located in the non-display area NDA. A pad, which is an area to which an electronic device or a printed circuit board can be electrically connected, may be located in the non-display area NDA.

In FIG. 1, a case where the display area DA is a polygon (e.g., a rectangle) whose length in a second direction DR2 is smaller than the length in a first direction DR1 is illustrated as an example. However, in another example, the display area DA may be a polygon (e.g., a quadrilateral) whose length in the first direction DR1 is smaller than or equal to the length in the second direction DR2.

In the drawings, the first direction DR1 and the second direction DR2 are horizontal directions crossing each other. For example, the first direction DR1 and the second direction DR2 may be orthogonal to each other. In addition, a third direction DR3 may be a vertical direction crossing, for example, orthogonal to the first direction DR1 and the second direction DR2. In the present specification, a direction indicated by an arrow of each of the first through third directions DR1 through DR3 may be referred to as one side, and the opposite direction may be referred to as the other side.

Although a case where the display area DA has a substantially rectangular shape is illustrated as an example, the present disclosure is not limited thereto. In another example, the display area DA may have various shapes such as an N-gon (where N is a natural number of 3 or greater), a circle, and an ellipse, and according to some embodiments, the corners or apexes of the N-gon may be rounded.

Although each corner of the display area DA is illustrated as including a vertex where straight lines meet, the present disclosure is not limited thereto. In another example, the display area DA may be a polygon with rounded corners.

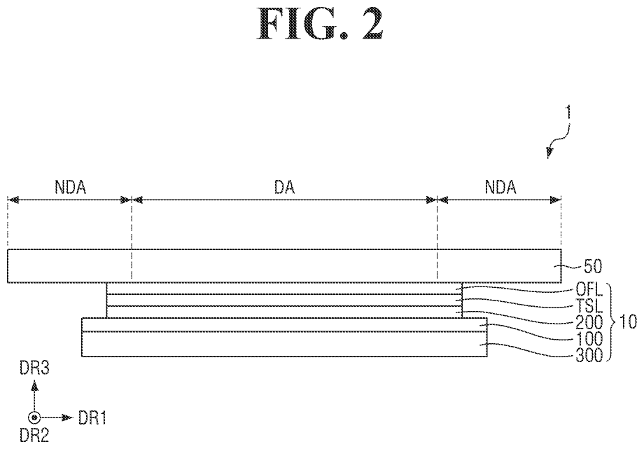

FIG. 2 is a schematic cross-sectional view of the display device 1 according to some embodiments.

Referring to FIG. 2, the display device 1 may include a display panel 10 and a cover window 50.

The display panel 10 may be a light emitting display panel including a light emitting element as a display element. For example, the display panel 10 may be an organic light emitting display panel using an organic light emitting diode that includes an organic light emitting layer, a micro-light emitting diode display panel using a micro-light emitting diode, a quantum dot light emitting display panel using a quantum dot light emitting diode that includes a quantum dot light emitting layer, or an inorganic light emitting display panel using an inorganic light emitting element that includes an inorganic semiconductor.

The display panel 10 may be a rigid display panel that is hard and not easily bent or a flexible display panel that is flexible and can be relatively easily bent, folded or rolled without damaging the display panel 10. For example, the display panel 10 may be a foldable display panel that can be folded or unfolded, a curved display panel whose display surface is curved, a bended display panel whose areas other than a display surface are bent, a rollable display panel that can be rolled or unrolled, or a stretchable display panel that can be stretched.

The display panel 10 may include a substrate 100, a display layer 200, a touch screen layer TSL, an optical functional layer OFL, and a protective member 300.

The substrate 100 may be made of an insulating material such as glass, quartz, or polymer resin.

According to some embodiments, substrate 100 may be a rigid substrate. For example, the substrate 100 may include at least one of glass or quartz.

According to some embodiments, the substrate 100 may be a flexible substrate that can be bent, folded, or rolled. For example, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

According to some embodiments, the substrate 100 may have a multilayer structure including a layer including the above polymer resin and an inorganic layer. For example, the substrate 100 may include two layers including the above polymer resin and an inorganic barrier layer interposed between the two layers.

The display layer 200 may be located on the substrate 100. The display layer 200 may be a layer including pixels and configured to display images. The display layer 200 may include a circuit layer including thin-film transistors, a display element layer in which display elements are located, and a sealing member for sealing the display element layer.

The display layer 200 may be divided into the display area DA and the non-display area NDA. The display area DA may be an area where pixels are arranged to display images. The non-display area NDA may be an area located outside (e.g., in a periphery or outside a footprint of) the display area DA and not displaying images. The non-display area NDA may surround the display area DA. The non-display area NDA may be an area extending from the outside of the display area DA to edges of the display panel 10. In the display area DA, not only pixels, but also pixel circuits for driving the pixels, scan lines connected to the pixel circuits, data lines, power lines, and the like may be located. In the non-display area NDA, a scan driver for transmitting scan signals to the scan lines, fan-out lines connecting the data lines and a display driver, and the like may be located.

Various functional layers may be located on the display layer 200 according to design. According to some embodiments, the touch screen layer TSL may be located on the display layer 200. The touch screen layer TSL may include touch electrodes and may be a layer for detecting a user's touch.

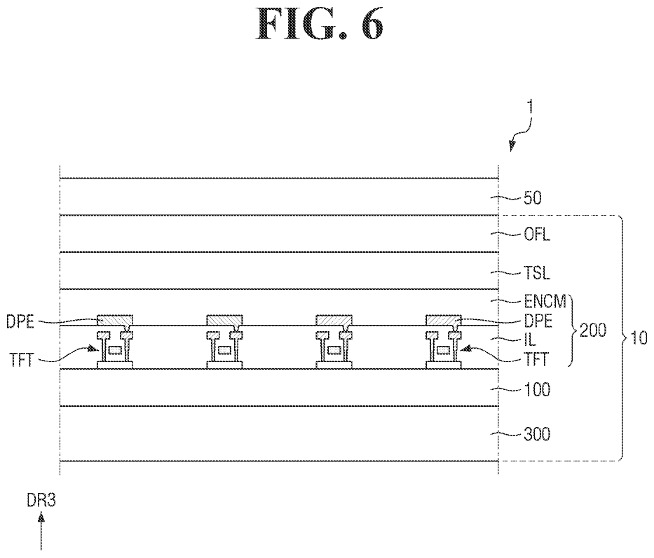

According to some embodiments, the touch screen layer TSL may be directly formed on an encapsulation member ENCM (see FIG. 6) of the display layer 200. For example, the display panel 10 may have an in-cell touch structure in which the touch screen layer TSL is directly located on the encapsulation member ENCM of the display layer 200.

According to some embodiments, the touch screen layer TSL may be separately formed and then bonded to the encapsulation member ENCM (see FIG. 6) of the display layer 200 through an adhesive layer such as an optically clear adhesive.

The optical functional layer OFL may be located on the touch screen layer TSL. The optical functional layer OFL may include an antireflection layer. The antireflection layer may reduce reflectance of light (external light) incident from the outside toward the display device 1.

In some embodiments, the antireflection layer may be provided as a polarizing film. The polarizing film may include a linear polarizing plate and a phase retardation film such as a quarter-wave (λ/4) plate. The phase retardation film may be located on the touch screen layer TSL, and the linear polarizing plate may be located on the phase retardation film.

The cover window 50 may be located on the optical functional layer OFL. The cover window 50 may be attached onto the optical functional layer OFL by a transparent adhesive member such as an optically clear adhesive film.

The cover window 50 may be located on the display panel 10 to cover an upper surface of the display panel 10. Therefore, the cover window 50 may function to protect the upper surface of the display panel 10.

According to some embodiments, the cover window 50 may be a flexible window. The cover window 50 may protect the display panel 10 while being easily bent according to an external force without cracks or the like. The cover window 50 may include glass, sapphire, or plastic. The cover window 50 may be, for example, ultra-thin glass (UTG) or colorless polyimide (CPI). According to some embodiments, the cover window 50 may have a structure in which a flexible polymer layer is located on a surface of a glass substrate or may be composed of only a polymer layer.

The protective member 300 may be located under the substrate 100. The protective member 300 may function to protect the display panel 10. For example, the protective member 300 may protect the display panel 10 from an impact transmitted from under the display panel 10 and may prevent components located on the protective member 300 from being deformed. In addition, the protective member 300 may include a material having excellent thermal conductivity to perform a heat dissipation function. The protective member 300 may also include a conductive material to absorb electromagnetic waves and prevent electrical interference. Furthermore, the protective member 300 may include a light blocking material to block light from the outside of the display device 1 and to reduce reflectance of light transmitted from above. Accordingly, the protective member 300 may relatively improve the reliability of the display panel 10.

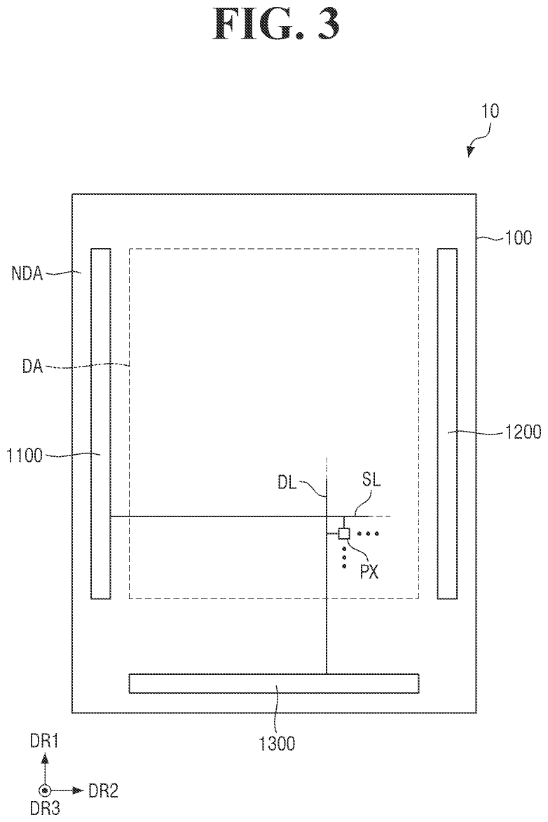

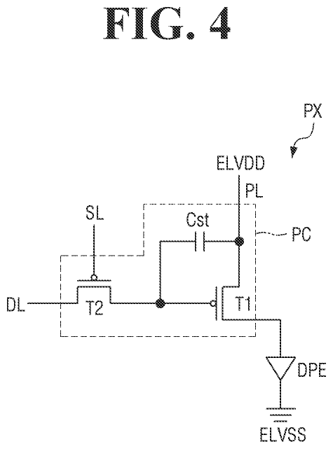

FIG. 3 is a schematic plan view of the display device 1 according to some embodiments. FIG. 4 is an equivalent circuit diagram of a pixel PX according to some embodiments.

Referring to FIGS. 3 and 4, the display panel 10 may include the display area DA and the non-display area NDA surrounding at least a part of the display area DA. The display panel 10 may include a plurality of pixels PX located in the display area DA. Each pixel PX may include a pixel circuit PC and a light emitting element DPE connected to the pixel circuit PC.

The pixel circuit PC may include a first transistor T1, a second transistor T2, and a storage capacitor Cst. Each pixel PX may emit, for example, red, green or blue light or red, green, blue or white light through the light emitting element DPE. The first transistor T1 and the second transistor T2 may be implemented as thin-film transistors.

The first transistor T1 is a driving transistor and connected to a driving voltage line PL and the storage capacitor Cst. The first transistor T1 may control a driving current flowing from the driving voltage line PL to the light emitting element DPE according to the value of a voltage stored in the storage capacitor Cst. The light emitting element DPE may emit light having a luminance (e.g., a set or predetermined luminance) in response to the driving current. A counter electrode (e.g., cathode) of the light emitting element DPE may receive a second power supply voltage ELVSS.

The second transistor T2 is a switching transistor and connected to a scan line SL and a data line DL. The second transistor T2 may transmit a data voltage received from the data line DL to the first transistor T1 according to a switching voltage received from the scan line SL. The storage capacitor Cst may be connected to the second transistor T2 and the driving voltage line PL and may store a voltage corresponding to a difference between a voltage received from the second transistor T2 and a first power supply voltage ELVDD supplied to the driving voltage line PL.

Although the pixel circuit PC includes two transistors and one storage capacitor in FIG. 4, embodiments according to the present disclosure are not limited thereto. That is, the number of thin-film transistors and the number of capacitors included in the pixel circuit PC may be variously changed according to the design of the pixel circuit PC. For example, the pixel circuit PC may further include four, five or more thin-film transistors in addition to the above two thin-film transistors. In addition, one or more capacitors may be further included in addition to the above storage capacitor Cst.

In addition, although a case where the first and second transistors T1 and T2 are PMOS transistors is illustrated as an example in the drawings, all or some of the transistors may also be NMOS transistors.

In the non-display area NDA, a first scan driver 1100 and a second scan driver 1200 providing scan signals to the pixels PX, a data driver 1300 providing data signals to the pixels PX, and a main power line for providing first and second power supply voltages may be located. The first scan driver 1100 and the second scan driver 1200 may be located in the non-display area NDA and may be located on both sides of the display area DA with the display area DA interposed between them, but the present disclosure is not limited thereto.

In FIG. 3, the data driver 1300 is located adjacent to a lower side of the substrate 100. However, according to some embodiments, the data driver 1300 may be located on a flexible printed circuit board (FPCB) electrically connected to a pad located on one side of the display panel 10.

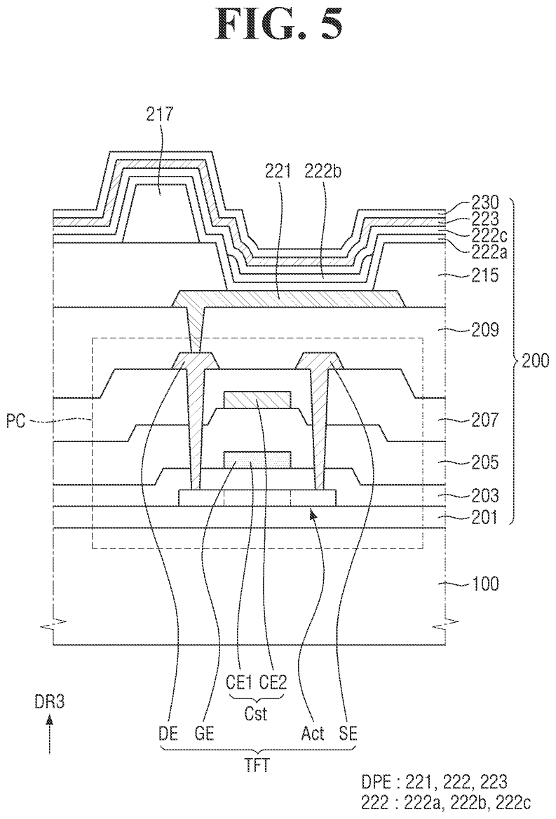

FIG. 5 is a schematic cross-sectional view of a portion of a display panel according to some embodiments.

Referring to FIG. 5, a pixel circuit PC may be located on a substrate 100, and a light emitting element DPE electrically connected to the pixel circuit PC may be located on the pixel circuit PC.

The substrate 100 may include at least one of glass, quartz, or polymer resin. The substrate 100 may have a single-layer or multilayer structure.

A buffer layer 201 may be located on the substrate 100. The buffer layer 201 may reduce or block the permeation of foreign substances, moisture, or outside air from under the substrate 100 and improve the smoothness of an upper surface of the substrate 100. The buffer layer 201 may include an inorganic material such as an oxide or a nitride, an organic material, or an organic/inorganic composite and may have a single-layer or multilayer structure of an inorganic material and an organic material. A barrier layer may be further included between the substrate 100 and the buffer layer 201 to block permeation of outside air.

The pixel circuit PC may be located on the buffer layer 201. The pixel circuit PC may include a thin-film transistor TFT and a storage capacitor Cst. The thin-film transistor TFT may include a semiconductor layer Act, a gate electrode GE, a source electrode SE, and a drain electrode DE. The current embodiment shows a top gate structure in which the gate electrode GE is located on the semiconductor layer Act with a gate insulating layer 203 interposed between them. However, in some embodiments, the thin-film transistor TFT may have a bottom gate structure.

The semiconductor layer Act may be located on the buffer layer 201. The semiconductor layer Act may include a channel region, and a source region and a drain region located on both sides of the channel region and doped with impurities. Here, the impurities may include N-type impurities or P-type impurities. The semiconductor layer Act may include amorphous silicon or polysilicon. As a specific example, the semiconductor layer Act may include an oxide of at least one material selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In addition, the semiconductor layer Act may include a Zn oxide-based material such as Zn oxide, In—Zn oxide, or Ga—In—Zn oxide. In addition, the semiconductor layer Act may be an IGZO (In—Ga—Zn—O), ITZO (In—Sn—Zn—O), or IGTZO (In—Ga—Sn—Zn—O) semiconductor in which a metal such as indium (In), gallium (Ga), or stannum (Sn) is contained in ZnO.

The gate electrode GE may be located on the semiconductor layer Act to overlap at least a portion of the semiconductor layer Act. For example, the gate electrode GE may overlap the channel region of the semiconductor layer Act. The gate electrode GE may include various conductive materials including molybdenum (Mo), aluminum (Al), copper (Cu) and titanium (Ti) and may have various layer structures. For example, the gate electrode GE may include a Mo layer and an Al layer or may have a multilayer structure of Mo/Al/Mo. In addition, in some embodiments, the gate electrode GE may have a multilayer structure including an ITO layer covering a metal material.

The gate insulating layer 203 between the semiconductor layer Act and the gate electrode GE may include an inorganic insulating material such as silicon oxide, silicon nitride, silicon oxynitride, aluminum oxide, titanium oxide, tantalum oxide, or hafnium oxide. The gate insulating layer 203 may be a single layer or a multilayer including the above materials.

The source electrode SE and the drain electrode DE may also include various conductive materials including molybdenum (Mo), aluminum (Al), copper (Cu) and titanium (Ti) and may have various layer structures. For example, the source electrode SE and the drain electrode DE may include a Ti layer and an Al layer or may have a multilayer structure of Ti/Al/Ti. The source electrode SE and the drain electrode DE may be connected to the source region and the drain region of the semiconductor layer Act through contact holes. In addition, in some embodiments, the source electrode SE and the drain electrode DE may have a multilayer structure including an ITO layer covering a metal material.

The storage capacitor Cst may include a lower electrode CE1 and an upper electrode CE2 overlapping each other with a first interlayer insulating layer 205 interposed between them. The storage capacitor Cst may overlap the thin-film transistor TFT. The lower electrode CE1 and the upper electrode CE2 overlap each other with the first interlayer insulating layer 205 interposed between them and form capacitance. In this case, the first interlayer insulating layer 205 serves as a dielectric layer of the storage capacitor Cst. In FIG. 5, the gate electrode GE of the thin-film transistor TFT is illustrated as the lower electrode CE1 of the storage capacitor Cst. According to some embodiments, the storage capacitor Cst may not overlap the thin-film transistor TFT. The storage capacitor Cst may be covered with a second interlayer insulating layer 207.

Each of the first interlayer insulating layer 205 and the second interlayer insulating layer 207 may include an inorganic insulating material such as silicon oxide, silicon nitride, silicon oxynitride, aluminum oxide, titanium oxide, tantalum oxide, or hafnium oxide. Each of the first interlayer insulating layer 205 and the second interlayer insulating layer 207 may be a single layer or a multilayer including the above materials.

The insulating layers 203, 205, 207, etc. including inorganic materials as described above may be formed through, but not limited to, chemical vapor deposition (CVD) or atomic layer deposition (ALD).

The pixel circuit PC including the thin-film transistor TFT and the storage capacitor Cst may be covered with an organic insulating layer 209. For example, the organic insulating layer 209 may cover the source electrode SE and the drain electrode DE. The organic insulating layer 209 may be located on the substrate 100 over the display area DA and the non-display area NDA outside the display area DA. The organic insulating layer 209 is a planarization insulating layer and may include a substantially flat upper surface. The organic insulating layer 209 may include an organic insulating material such as a general-purpose polymer such as polymethylmethacrylate (PMMA) or polystylene (PS), a polymer derivative having a phenolic group, an acrylic polymer, an imide polymer, an arylether polymer, an amide polymer, a fluorine polymer, a p-xylene-based polymer, a vinyl alcohol-based polymer, or a blend thereof. According to some embodiments, the organic insulating layer 209 may include polyimide.

A pixel electrode 221 may be formed on the organic insulating layer 209. The pixel electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to some embodiments, the pixel electrode 221 may further include a layer made of ITO, IZO, ZnO, or In₂O₃ and located on/under the reflective layer.

A bank layer 215 may be formed on the pixel electrode 221. The bank layer 215 may include an opening exposing an upper surface of the pixel electrode 221 but may cover edges of the pixel electrode 221. The bank layer 215 may include an organic insulating material. Alternatively, the bank layer 215 may include an inorganic insulating material such as silicon nitride, silicon oxynitride, or silicon oxide. Alternatively, the bank layer 215 may include an organic insulating material and an inorganic insulating material.

An intermediate layer 222 may include a light emitting layer 222b. The light emitting layer 222b may include, for example, an organic material. The light emitting layer 222b may include a polymer or low molecular weight organic material that emits light of a color (e.g., a set or predetermined color). The intermediate layer 222 may include a first functional layer 222a located under the light emitting layer 222b and/or a second functional layer 222c located on the light emitting layer 222b.

The first functional layer 222a may be a single layer or a multilayer. For example, when the first functional layer 222a is made of a polymer material, it may be a hole transport layer (HTL) having a single-layer structure and may be made of poly-(3,4)-ethylene-dihydroxy thiophene (PEDOT) or polyaniline (PANI). When the first functional layer 222a is made of a low molecular weight material, it may include a hole injection layer (HIL) and an HTL.

The second functional layer 222c may be optional. For example, when the first functional layer 222a and the light emitting layer 222b are made of a polymer material, the second functional layer 222c may be formed. The second functional layer 222c may be a single layer or a multilayer. The second functional layer 222c may include an electron transport layer (ETL) and/or an electron injection layer (EIL).

The light emitting layer 222b of the intermediate layer 222 may be separately located in each pixel in the display area DA. The light emitting layer 222b may overlap the opening of the bank layer 215 or/and the pixel electrode 221. Each of the first and second functional layers 222a and 222c of the intermediate layer 222 may be formed as a single body.

A counter electrode 223 may be made of a conductive material having a low work function. For example, the counter electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 223 may further include a layer such as ITO, IZO, ZnO, or In₂O₃ on the (semi) transparent layer including the above materials. The counter electrode 223 may be a single body and may be formed to cover a plurality of pixel electrodes 221 in the display area DA. The intermediate layer 222 and the counter electrode 223 may be formed by thermal evaporation.

A spacer 217 may be located on the bank layer 215. The spacer 217 may prevent damage to a light emitting diode or the like by securing a space (e.g., a set or predetermined space) on a display element.

The spacer 217 may include an organic insulating material such as polyimide. Alternatively, the spacer 217 may include an inorganic insulating material such as silicon nitride or silicon oxide or may include an organic insulating material and an inorganic insulating material. In addition, the spacer 217 may include a material different from that of the bank layer 215. Alternatively, the spacer 217 may include the same material as the bank layer 215. In this case, the bank layer 215 and the spacer 217 may be formed together in a mask process using a halftone mask or the like.

A capping layer 230 may be located on the counter electrode 223. The capping layer 230 may include LiF, an inorganic material, or/and an organic material. In some embodiments, the capping layer 230 may be omitted.

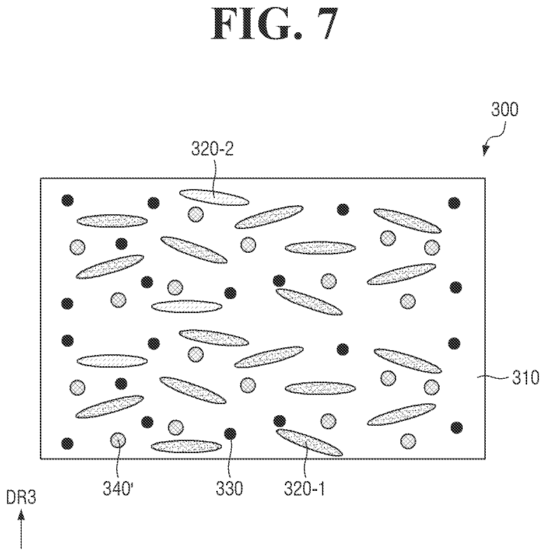

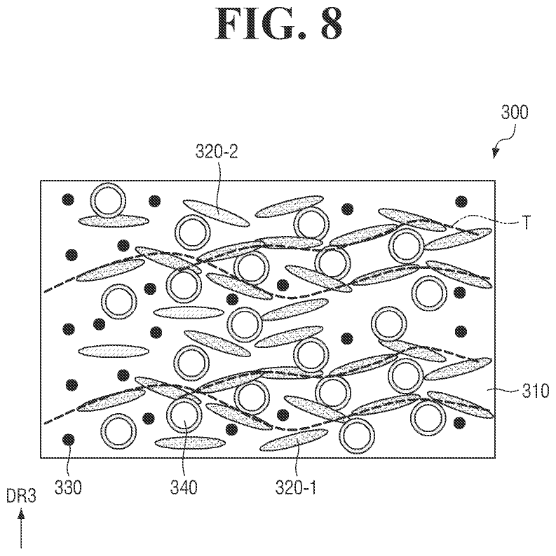

FIG. 6 is a schematic cross-sectional view of a portion of the display device 1 according to some embodiments. FIG. 7 schematically illustrates the state of a protective member 300 before being cured according to some embodiments. FIG. 8 schematically illustrates the state of the protective member 300 after being cured according to some embodiments.

Referring to FIGS. 6 through 8, the cover window 50 may be located on the display panel 10. The cover window 50 may be located on the display panel 10 to entirely cover the display panel 10.

The display panel 10 may include the substrate 100, the display layer 200 located on the upper surface of the substrate 100, functional layers, for example, the touch screen layer TSL and the optical functional layer OFL located on an upper surface of the display layer 200, and the protective member 300 located under the substrate 100.

An insulating layer IL may be located between the substrate 100 and the display layer 200 and within the display layer 200. For example, as described above with reference to FIG. 5, the display layer 200 may include the buffer layer 201, the gate insulating layer 203, the first interlayer insulating layer 205, the second interlayer insulating layer 207, and the organic insulating layer 209 as insulating layer IL.

According to some embodiments, the display layer 200 of the display panel 10 may further include the encapsulation member ENCM. The encapsulation member ENCM may be an encapsulation layer for protecting light emitting elements DPE of the display layer 200 from moisture or oxygen from the outside. The encapsulation layer may include at least one organic encapsulating layer and at least one inorganic encapsulating layer. For example, the encapsulation layer may include a first inorganic encapsulating layer, an organic encapsulating layer, and a second inorganic encapsulating layer.

When the light emitting elements DPE are organic light emitting diodes, the first inorganic encapsulating layer may cover the counter electrode 223 (see FIG. 5) and may include silicon oxide, silicon nitride, and/or silicon trioxynitride. Other layers such as the capping layer 230 (see FIG. 5) may also be interposed between the first inorganic encapsulating layer and the counter electrode 223 (see FIG. 5). Because the first inorganic encapsulating layer is formed along structures thereunder, its upper surface may not be flat or planar. Therefore, the organic encapsulating layer may be formed to cover the first inorganic encapsulating layer so that the upper surface of the first inorganic encapsulating layer may be flat or planar. The organic encapsulating layer may include one or more materials selected from polyethylene terephthalate, polyethylene naphthalate, polycarbonate, polyimide, polyethylene sulfonate, polyoxymethylene, polyarylate, and hexamethyldisiloxane. The second inorganic encapsulating layer may cover the organic encapsulating layer and may include silicon oxide, silicon nitride, silicon trioxynitride, or the like.

The protective member 300 may be located under the substrate 100. The protective member 300 may include a binder 310, first fillers 320-1, second fillers 320-2, light blocking materials 330, and foaming agents 340 or 340′. A thickness of the protective member 300 after being cured may be 100 to 300 μm.

The first fillers 320-1 may have heat dissipation characteristics. Accordingly, the first fillers 320-1 may include a material having excellent thermal conductivity. The first fillers 320-1 may include at least one of a carbon-based material or a ceramic-based material. For example, when the first fillers 320-1 include a carbon-based material, they may include at least one of graphite, carbon nanotube (CNT), or carbon fiber. When the first fillers 320-1 include a ceramic-based material, they may include at least one of boron nitride (BN), aluminum nitride (AlN), beryllium oxide (BeO), silicon carbide (SiC), or aluminum oxide (Al₂O₃, alumina).

The first fillers 320-1 may be plate-shaped fillers or linear fillers. Here, the first fillers 320-1 may have a particle size of 5 to 200 μm. Accordingly, some of the first fillers 320-1 may contact each other to form a heat dissipation path. For example, when the first fillers 320-1 are plate-shaped fillers, some of the first fillers 320-1 may come into surface contact with each other to form a heat dissipation path. When the first fillers 320-1 are linear fillers, some of the first fillers 320-1 may come into line contact with each other to form a heat dissipation path. When the first fillers 320-1 are plate-shaped or linear fillers, they may come into surface contact or line contact with each other to increase a contact area between them. Therefore, a heat dissipation path can be easily formed.

The first fillers 320-1 may be included in an amount of 50 to 80% by weight based on the total weight of the protective member 300. Here, the first fillers 320-1 may be made of a mixture of a carbon-based material and a ceramic-based material and may occupy 50 to 80% by weight of the protective member 300. However, the present disclosure is not limited thereto, and the first fillers 320-1 may also be made of only a carbon-based material or only a ceramic-based material.

Because the first fillers 320-1 occupy 50 to 80% by weight which is more than half of the total weight of the protective member 300, the first fillers 320-1 located adjacent to each other may come into contact with each other and easily form a heat dissipation path. Accordingly, the protective member 300 including the first fillers 320-1 can effectively dissipate heat generated from the display panel 10.

The second fillers 320-2 may have electromagnetic wave shielding characteristics. Accordingly, the second fillers 320-2 may include a material having excellent electrical conductivity. The second fillers 320-2 may include at least one of a carbon-based material or a metal-based material. For example, when the second fillers 320-2 include a carbon-based material, they may include at least one of carbon fiber or carbon nanotube (CNT). When the second fillers 320-2 include a metal-based material, they may include at least one of silver-copper (Ag—Cu), nickel-copper (Ni—Cu), silver (Ag) nano wire, or silver-nickel (Ag—Ni) powder.

When the first fillers 320-1 include a carbon-based material, they may also block electromagnetic waves to some extent. However, the second fillers 320-2 may be added to further increase an electromagnetic wave shielding rate. Here, the second fillers 320-2 may be included in an amount of 1 to 10% by weight based on the total weight of the protective member 300. According to some embodiments, the electromagnetic wave shielding rate of the protective member 300 including the first fillers 320-1 and the second fillers 320-2 may be 40 to 90 dB, preferably, 60 to 80 dB.

Consequently, the content of the first fillers 320-1 and the second fillers 320-2 in the protective member 300 may be 51 to 90% by weight based on the total weight of the protective member 300. More preferably, the first fillers 320-1 and the second fillers 320-2 may occupy 85% by weight or less based on the total weight of the protective member 300. Because the first fillers 320-1 and the second fillers 320-2 are included at 85% by weight or less, the binder 310 for fixing the first fillers 320-1 and the second fillers 320-2 may be sufficiently included. Therefore, the adhesiveness of the protective member 300 can be improved. Accordingly, the protective member 300 can be applied and bonded to the substrate 100 without a separate adhesive layer.

The binder 310 may fix the first fillers 320-1 and the second fillers 320-2. The binder 310 may include at least one of acrylic resin, urethane resin, silicone resin, or rubber resin. For example, the binder 310 may be made of acrylate, urethane, urethane acrylate, silicone, rubber, or a combination thereof. However, the present disclosure is not limited thereto, and any material having sufficient bonding strength to fix the first fillers 320-1 and the second fillers 320-2 can be used.

The binder 310 may not only fix the first fillers 320-1 and the second fillers 320-2 but also absorb the impact applied to the display device 1. That is, due to modulus characteristics of the binder 310 itself, the protective member 300 can protect the display panel 10 from impact transmitted from under the protective member 300. However, the impact resistance of the protective member 300 may be improved not only by the elasticity of the binder 310 itself but also by the content of the fillers and the content of the foaming agents 340 to be described in more detail later. According to some embodiments, based on when a steel ball of 2.0 g is dropped from a height of 10 cm, the amount of impact received by pressure sensitive paper located under the protective member 300 may be 10 to 40 MPa.

In addition, the protective member 300 may further include a solvent that can dissolve the binder 310. The solvent is volatilized during a thermal curing process of the protective member 300, but a portion of the solvent may remain in the protective member 300. The solvent included in the protective member 300 may have a boiling point of 100 to 200° C. This is because, when the boiling point of the solvent is 100° C. or less, the solvent may be volatilized during a process of forming the protective member 300 performed before the thermal curing process. In addition, because the solvent must be compatible with the binder 310 including at least one of acrylic resin, urethane resin, silicone resin, or rubber resin, the solvent may include at least one of alcohol-based, ester-based, ketone-based, or glycol-based solvents. For example, the solvent may include an alcohol-based solvent such as isobutanol, butanol, or 2-(2-ethoxyethoxy) ethanol. The solvent may include an ester-based solvent such as butyl acetate or isobutyl acetate. The solvent may include a ketone-based solvent such as methyl isobutyl ketone. The solvent may include a glycol-based solvent such as propylene glycol methyl ether (PGME) or ethylene glycol monopropyl ether (EGPE).

Next, the light blocking materials 330 may block light incident from under the display panel 10 and may reduce reflectance of light transmitted from above. For example, the light blocking materials 330 may include at least one of carbon black, black pigment, or black dye. When the first fillers 320-1 and the second fillers 320-2 include a carbon-based material, they may also block light to some extent. However, the light blocking materials 330 may be further included to further lower the transmittance of light incident from under the display panel 10. According to some embodiments, the light blocking materials 330 may be included in an amount of 1 to 5% by weight based on the total weight of the protective member 300.

Next, the foaming agents 340 or 340′ may be materials whose volume increases when the protective member 300 is cured by heat or ultraviolet light. FIG. 7 shows a state before the volume of the foaming agents 340 of FIG. 8 is increased, that is, before the protective member 300 is cured, and FIG. 8 shows a state after the volume of the foaming agents 340′ of FIG. 7 is increased, that is, after the protective member 300 is cured. Each of the foaming agents 340 or 340′ may have a structure including a core portion and an outer cover surrounding the core portion. When heat or ultraviolet light is provided, a foaming material included in the core portion may vaporize, thereby increasing the volume of the foaming agents 340′. In each foaming agent 340 after being foamed, the volume of the core portion may increase, and the outer cover may be thinner than that in each foaming agent 340′ before being foamed.

According to some embodiments, the foaming agents 340 or 340′ may be thermo-expandable microcapsules. That is, when the foaming agents 340′ are heated, the outer cover may soften while the foaming material vaporizes. Thus, the volume of the foaming agents 340′ may expand. The foaming agents 340 or 340′ may be low-temperature foaming agents and may start to be foamed at a temperature of about 70° C. Because the foaming agents 340 or 340′ can be foamed at a low temperature, it is possible to perform the foaming process without damaging organic light emitting elements included in the display panel 10.

The foaming process of the foaming agents 340′ may be performed together with the curing process of the protective member 300. However, embodiments according to the present disclosure is not limited thereto, and the foaming process of the foaming agents 340′ and the curing process of the protective member 300 may also be performed as separate processes.

The foaming agents 340′ may be included in an amount of 1 to 10% by weight based on the total weight of the protective member 300. The protective member 300 may be made to have an elasticity (e.g., a set or predetermined elasticity) and impact resistance by adjusting the content of the foaming agents 340′.

The foaming agents 340 or 340′ may be dispersed within the protective member 300 and may have the same size. According to some embodiments, the particle size of the foaming agents 340′ after being foamed may be 10 to 100 μm. However, embodiments according to the present disclosure are not limited thereto, and the foaming agents 340 or 340′ may also have different sizes. In addition, although the foaming agents 340 or 340′ have a spherical shape in FIGS. 7 and 8, the present disclosure not limited thereto, and the foaming agents 340 or 340′ may also have an elliptical shape.

As the volume of the foaming agents 340′ increases, an area in which the first fillers 320-1 included in the protective member 300 can be dispersed may decrease. That is, when the volume of the foaming agents 340′ increases, the first fillers 320-1 may be located closer to each other, and some of the first fillers 320-1 may contact each other to form a heat dissipation path. Ultimately, the protective member 300 including the foaming agents 340 or 340′ can more easily form a heat dissipation path of the first fillers 320-1 having heat dissipation characteristics. Therefore, the protective member 300 can effectively dissipate heat generated from the display panel 10. Accordingly, the thermal conductivity of the protective member 300 including the foaming agents 340 or 340′ and the first fillers 320-1 may be 10 to 50 W/mK.

The protective member 300 may be formed to have high viscosity. For example, the protective member 300 may have a viscosity of 10,000 to 50,000 cPs. According to some embodiments, the viscosity of the protective member 300 may be 20,000 to 40,000 cPs.

As described above, the protective member 300 may perform multiple functions of protecting the display panel 10. For example, the protective member 300 may protect the display panel 10 from an impact transmitted from under the display device 1, perform a heat dissipation function, and block electromagnetic waves and light. In the conventional art, a protective member performing the above protective functions is formed by manufacturing a plurality of functional layers respectively having impact resistance, heat dissipation, electromagnetic wave blocking and light blocking functions, forming a composite sheet through a lamination process, and then attaching the composite sheet to a display panel through a lamination process. Therefore, a unit cost of an alternative protective member may be relatively high due to the manufacturing and laminating processes of the functional layers, and the risk of defects may be relatively higher. However, when the protective member 300 is directly applied to a lower surface of the substrate 100, it can perform the multiple functions of protecting the display panel 10 while the cost may be relatively reduced due to simplification of structure and material, and the risk of defects is greatly reduced due to simplification of process.

A method of manufacturing a display device according to some embodiments will now be described.

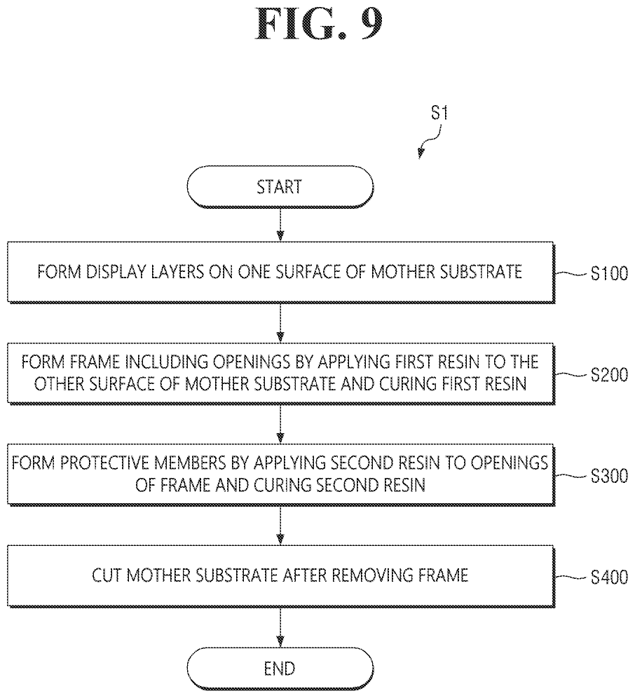

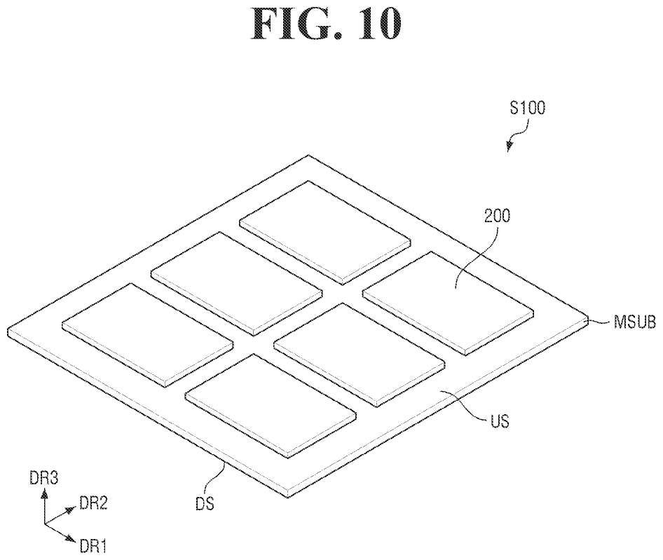

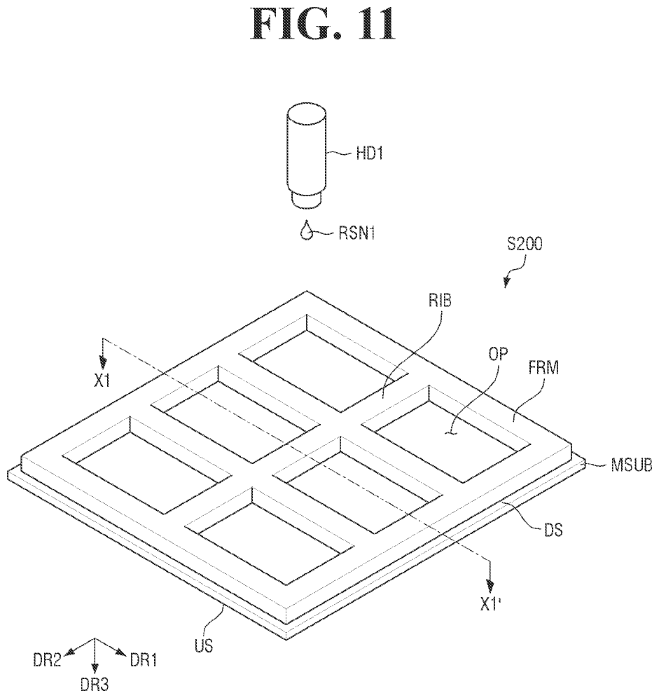

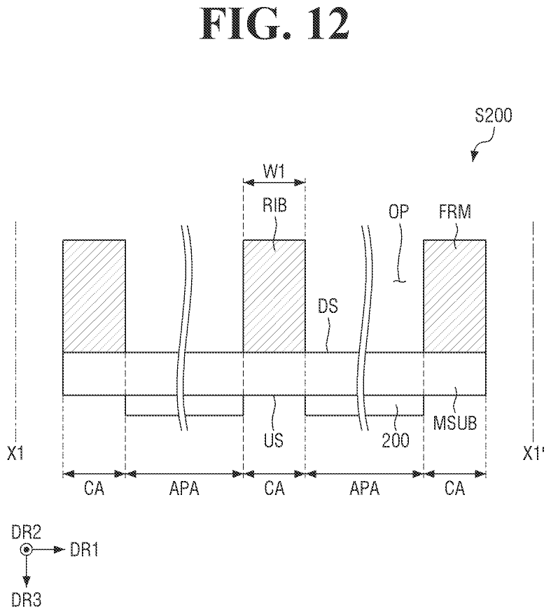

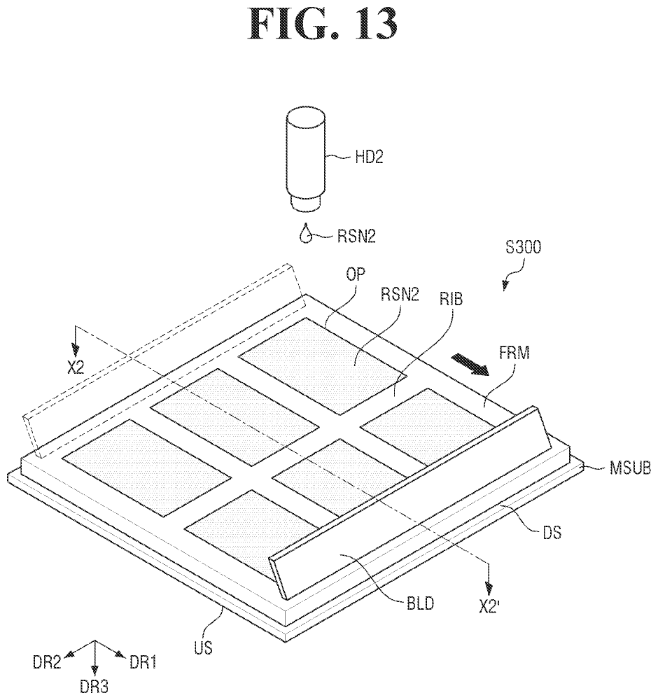

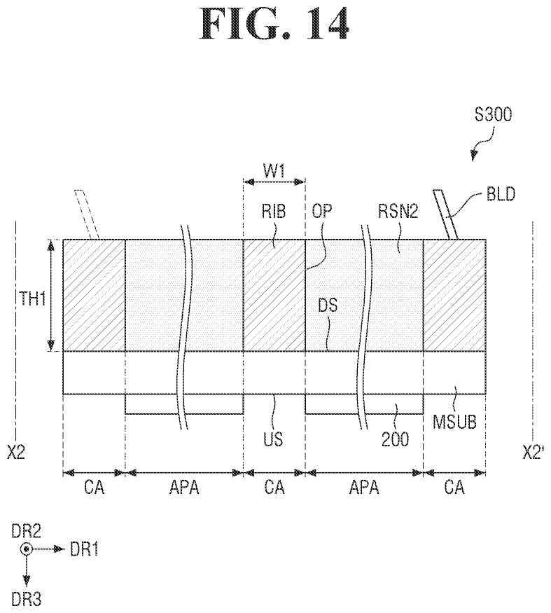

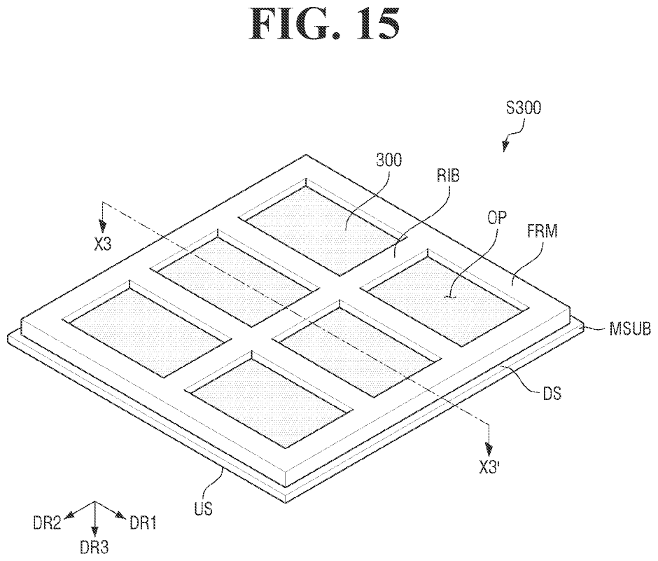

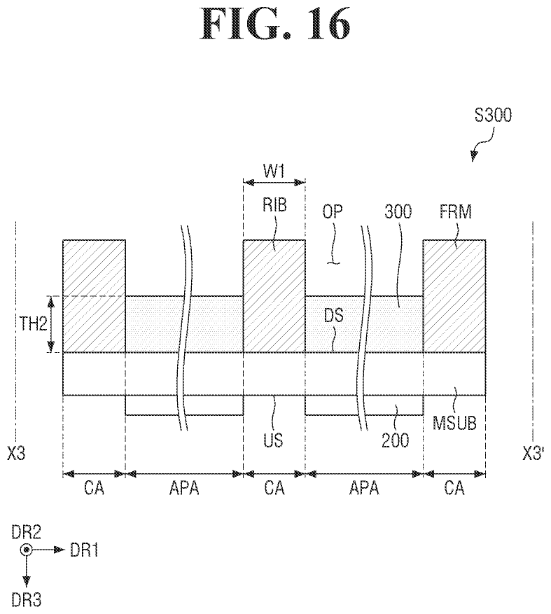

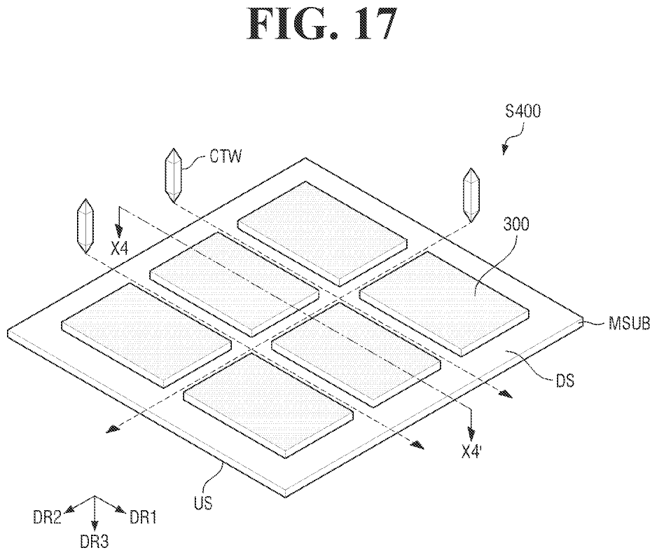

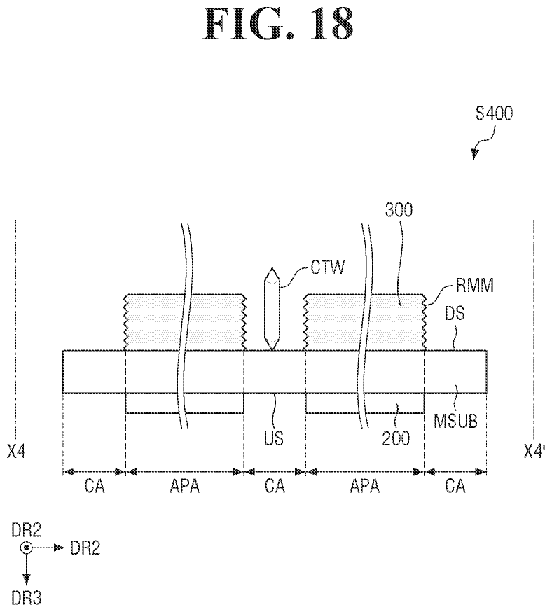

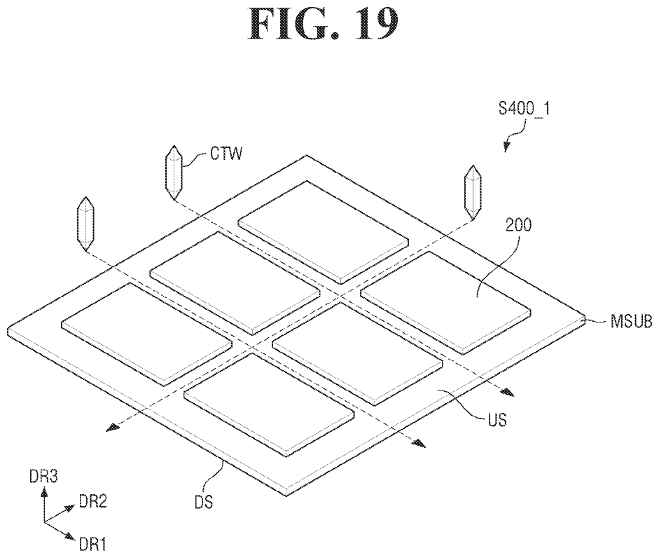

FIG. 9 is a flowchart illustrating a method of manufacturing a display device according to some embodiments. FIG. 10 is a perspective view illustrating operation S100 of FIG. 9. FIG. 11 is a perspective view illustrating operation S200 of FIG. 9. FIG. 12 is a cross-sectional view taken along line X1-X1′ of FIG. 11. FIG. 13 is a perspective view illustrating operation S300 of FIG. 9. FIG. 14 is a cross-sectional view taken along line X2-X2′ of FIG. 13. FIG. 15 is a perspective view illustrating operation S300 of FIG. 9. FIG. 16 is a cross-sectional view taken along line X3-X3′ of FIG. 15. FIG. 17 is a perspective view illustrating operation S400 of FIG. 9. FIG. 18 is a cross-sectional view taken along line X4-X4′ of FIG. 17. FIG. 19 is a perspective view illustrating an embodiment of operation S400 of FIG. 17.

Referring to FIGS. 9 through 19, the method S1 of manufacturing the display device according to the embodiment may include forming display layers on one surface of a mother substrate (operation S100), forming a frame including openings by applying a first resin to the other surface of the mother substrate and curing the first resin (operation S200), forming protective members by applying a second resin to the openings of the frame and curing the second resin (operation S300), and cutting the mother substrate after removing the frame (operation S400).

First, as illustrated in FIG. 10, in the forming of the display layers on the one surface of the mother substrate (operation S100), display layers 200 may be formed on a surface, for example, an upper surface US of a mother substrate MSUB. For example, as illustrated in FIG. 10, in order to form the display layers 200, the mother substrate MSUB may be placed such that the third direction DR3 in which the upper surface US faces is upward in the drawing and that the opposite direction in which a lower surface DS faces is downward in the drawing.

The mother substrate MSUB may be made of the same material as the above-described substrate 100 (see FIG. 2). For example, the mother substrate MSUB may include at least one of glass, quartz, or polymer resin. Because the display layers 200 have been described above, some repetitive description thereof may be omitted. Horizontal and vertical lengths of the mother substrate MSUB may be about several meters. For example, the mother substrate MSUB may have a horizontal length of about 2.5 m and a vertical length of about 2 m, but embodiments according to the present disclosure are not limited thereto.

The display layers 200 may be located on the upper surface US of the mother substrate MSUB at regular intervals along the first direction DR1 and the second direction DR2. For example, the display layers 200 may be located in a matrix direction to form display cells, respectively.

Next, as illustrated in FIGS. 11 and 12, in the forming of the frame including the openings by applying the first resin to the other surface of the mother substrate and curing the first resin (operation S200), in order to perform a process of applying protective members 300 under the mother substrate MSUB, the mother substrate MSUB may be placed such that the upper surface US faces downward and the lower surface DS faces upward.

The mother substrate MSUB may include application areas APA overlapping the display layers 200 in the third direction DR3 and a cutting area CA surrounding the application areas APA.

The application areas APA may be areas to which a second resin RSN2 to be described later is applied and may be areas overlapping the display layers 200. For example, the application areas APA may have substantially the same area as the display layers 200 and may completely overlap the display layers 200. However, embodiments according to the present disclosure are not limited thereto, and the application areas APA may also generally overlap the display layers 200, but may have a smaller or larger area than the display layers 200. The application areas APA may overlap the display cells.

The cutting area CA may surround the application areas APA. The cutting area CA may generally not overlap the display layers 200. However, embodiments according to the present disclosure are not limited thereto, and the cutting area CA may also partially overlap the display layers 200. The cutting area CA may be an area through which a cutting line of a cutting member passes in a cutting process to be described later. The cutting area CA may be located between the application areas APA or around the application areas APA.

A first resin RSN1 may be applied onto the cutting area CA through a first applying head HD1. The first resin RSN1 may be applied onto the cutting area CA using any one of a printing method, a coating method, and a dispensing method through the first applying head HD1. According to some embodiments, the first applying head HD1 may quickly and accurately apply the first resin RSN1 onto the cutting area CA using the dispensing method, but embodiments according to the present disclosure are not limited thereto.

The first resin RSN1 may include at least one of acrylic resin, urethane resin, silicone resin, or rubber resin. For example, a binder 310 may be made of acrylate, urethane, urethane acrylate, silicone, rubber, or a combination thereof. According to some embodiments, the first resin RSN1 may include the same material as a binder 310 (see FIG. 7) of the second resin RSN2 to be described later.

A thickness of the first resin RSN1 after being cured may be greater than or equal to a thickness of the second resin RSN2 before being cured. That is, a thickness of a frame FRM may be greater than or equal to the thickness of the second resin RSN2 before being cured. For example, the thickness of the first resin RSN1 after being cured may be 200 to 600 μm.

The first resin RSN1 may have substantially the same thickness before and after being cured. For example, the thickness of the first resin RSN1 before and after being cured may be about 200 to 600 μm. According to some embodiments, the thickness of the first resin RSN1 before and after being cured may be about 400 μm. Unlike the second resin RSN2 to be described later, the first resin RSN1 may have substantially the same thickness before and after being cured because it hardly includes a highly volatile solvent. However, embodiments according to the present disclosure are not limited thereto, and the first resin RSN1 may also have different thicknesses before and after being cured if it includes a highly volatile solvent.

The first resin RSN1 may be cured through a curing process to form the frame FRM. The first resin RSN1 may be cured through at least one of thermal curing, natural curing, or ultraviolet curing. According to some embodiments, the first resin RSN1 may be cured through at least one of thermal curing or natural curing. When the first resin RSN1 is cured through at least one of thermal curing or natural curing, an elongation rate of the frame FRM may be improved.

According to some embodiments, when thermal curing is used, a heat treatment process may be performed at a temperature of 25 to 100° C. or less for about one hour. According to some embodiments, the heat treatment process may be performed at a temperature of about 90° C. Because the heat treatment process is performed at a relatively low temperature, the display panel 10 including the display layers 200 may not be damaged.

The frame FRM may have a relatively high elongation rate. For example, the elongation rate of the frame FRM may be 200% or more. When the elongation rate of the frame FRM is 200% or more, the frame FRM can be easily removed without breakage or residue in a removal process of the frame FRM which will be described in more detail later.

The frame FRM may be located on the cutting area CA. The frame FRM may surround the application areas APA. The frame FRM may include openings OP. The openings OP may overlap the application areas APA. The openings OP may overlap the display layers 200. Each of the openings OP may provide a space to which the second resin RSN2 to be described later is applied.

The frame FRM may include a rib RIB located between the openings OP. A width W1 of the rib RIB may be about 1 to 5 mm.

Next, as illustrated in FIGS. 13 through 16, in the forming of the protective members by applying the second resin to the openings of the frame and curing the second resin (operation S300), the second resin RSN2 may be applied onto the application areas APA through a second applying head HD2 and a blade (or squeegee) BLD. The second resin RSN2 may be applied onto the application areas APA using any one of a printing method, a coating method, and a dispensing method through the second applying head HD2 and the blade BLD. According to some embodiments, the second applying head HD2 may eject the second resin RSN2 in paste form onto one side of the frame FRM by using a dispensing method. The blade BLD may move while pushing the second resin RSN2 ejected in the paste form from one side of the frame FRM to the other side of the frame FRM by using a screen printing method. Accordingly, the second resin RSN2 may be applied on the application areas APA.

A diameter of an outlet of the second applying head HD2 may be greater than that of an outlet of the first applying head HD1. A maximum diameter of particles of the second resin RSN2 ejected from the second applying head HD2 may be greater than a maximum diameter of particles of the first resin RSN1 ejected from the first applying head HD1.

As described above with reference to FIG. 7, etc., the second resin RSN2 may include the binder 310 (see FIG. 7), first fillers 320-1 (see FIG. 7), second fillers 320-2 (see FIG. 7), light blocking materials 330 (see FIG. 7), foaming agents 340 (see FIG. 7), and a solvent.

A thickness TH1 of the second resin RSN2 before being cured may be smaller than or equal to the thickness of the frame FRM. For example, the thickness TH1 of the second resin RSN2 before being cured may be 200 to 600 μm.

A thickness TH2 of the second resin RSN2 after being cured may be smaller than the thickness TH1 of the second resin RSN2 before being cured. For example, the thickness TH2 of the second resin RSN2 after being cured may be about 40 to 60% of the thickness TH1 of the first resin RSN1 before being cured. The thickness TH2 of the second resin RSN2 after being cured may be 100 to 300 μm.

The second resin RSN2 may be cured through a curing process to form the protective members 300. The second resin RSN2 may be cured through at least one of thermal curing, natural curing, or ultraviolet curing. According to some embodiments, the second resin RSN2 may be cured through at least one of thermal curing or natural curing. When the second resin RSN2 is cured through at least one of thermal curing or natural curing, the strength and elasticity of the protective members 300 may be relatively increased.

According to some embodiments, when thermal curing is used, a heat treatment process may be performed at a temperature of 25 to 100° C. or less for about one hour. According to some embodiments, the heat treatment process may be performed at a temperature of about 90° C. Because the heat treatment process is performed at a relatively low temperature, the display panel 10 including the display layers 200 may not be damaged.

The protective members 300 may be located on the application areas APA. The protective members 300 may be surrounded by the frame FRM located on the cutting area CA. The protective members 300 may be located inside the openings OP of the frame FRM.

A thickness TH2 of each protective member 300, that is, the thickness TH2 of the second resin RSN2 after being cured may be about 100 to 300 μm.

Next, as illustrated in FIGS. 17 and 18, in the cutting of the mother substrate after removing the frame (operation S400), the frame FRM may be removed from the mother substrate MSUB. As described above, because the elongation rate of the frame FRM is high, the frame FRM can be easily removed without a residue on the mother substrate MSUB.

A cutting member CTW may cut the mother substrate MSUB. The cutting member CTW may cut the mother substrate MSUB along a cutting line located in the cutting area CA from which the frame FRM has been removed. The cutting member CTW may be a cutting wheel or a laser. The mother substrate MSUB cut by the cutting member CTW may form the substrate 100 (see FIG. 2) of each display cell, and the display layer 200 may be located on the substrate 100 (see FIG. 2) of each display cell.

In the method S1 of manufacturing the display device according to some embodiments, the frame FRM is formed using the first resin RSN1 different from the second resin RSN2 before the second resin RSN2 is applied. Therefore, the yield of the process of forming the protective members 300 can be improved. For example, when the second resin RSN2 is applied using a mask using a metal material as in the conventional art, the width W1 of the rib RIB is significantly small compared with the total size of the mask. Therefore, there may occur a lifting phenomenon or a phenomenon in which the second resin RSN2 penetrates into the cutting area CA rather than the application areas APA. On the other hand, when the second resin RSN2 is applied using the frame FRM including the first resin RSN1, the penetration of the second resin RSN2 into the cutting area CA can be prevented due to the adhesive strength of the first resin RSN1 to the mother substrate MSUB. In addition, because the frame FRM has a high elongation rate, it can be relatively easily removed. Furthermore, because the second resin RSN2 does not penetrate into the cutting area CA and leaves no foreign matter, contamination of a cutting member during a cutting process can be prevented.

In some embodiments, removal marks RMM may be formed on side surfaces of the protective members 300 which directly contact the frame FRM. For example, due to the adhesive strength between the frame FRM and the protective members 300, the removal marks RMM may be formed on the side surfaces of the protective members 300 when the frame FRM is removed.

As illustrated in FIG. 19, according to some embodiments, a cutting process may be performed in a state where the mother substrate MSUB is placed such that the third direction DR3 in which the upper surface US of the mother substrate MSUB faces is upward in the drawing and that the opposite direction in which the lower surface DS of the mother substrate MSUB faces is downward in the drawing. That is, the cutting process may be performed in a direction from the upper surface US where the display layers 200 are located toward the lower surface DS where the protective members 300 are located.

In some embodiments, when the mother substrate MSUB includes two or more layers of substrates, each substrate may be cut separately. For example, when the mother substrate MSUB includes two layers of substrates, a substrate located on the lower surface side DS of the mother substrate MSUB may be cut first as illustrated in FIG. 17, and then a substrate located on the upper surface side US of the mother substrate MSUB may be cut as illustrated in FIG. 19. The opposite is also possible. That is, the substrate located on the upper surface side US of the mother substrate MSUB may be cut first, and then the substrate located on the lower surface side DS of the mother substrate MSUB may be cut.

A method of manufacturing a display device according to an embodiment will now be described. According to some embodiments, the same elements as those of the above-described embodiment will be indicated by the same reference numerals, and some repetitive description may be omitted or given briefly, and differences will be mainly described.

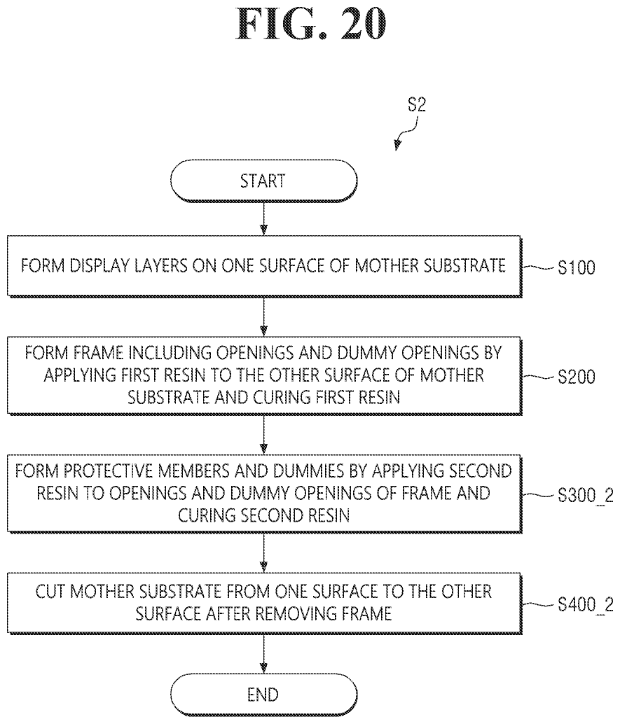

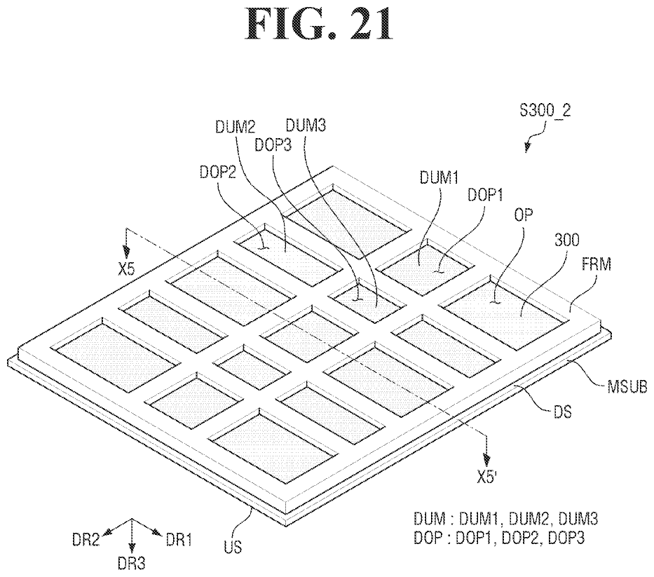

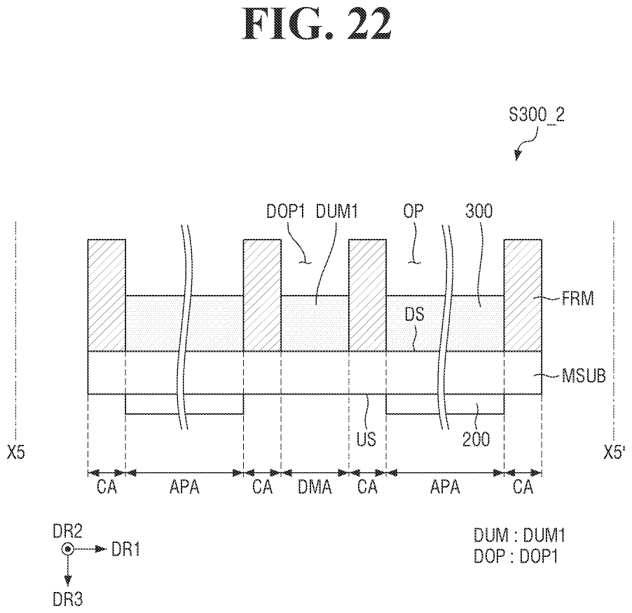

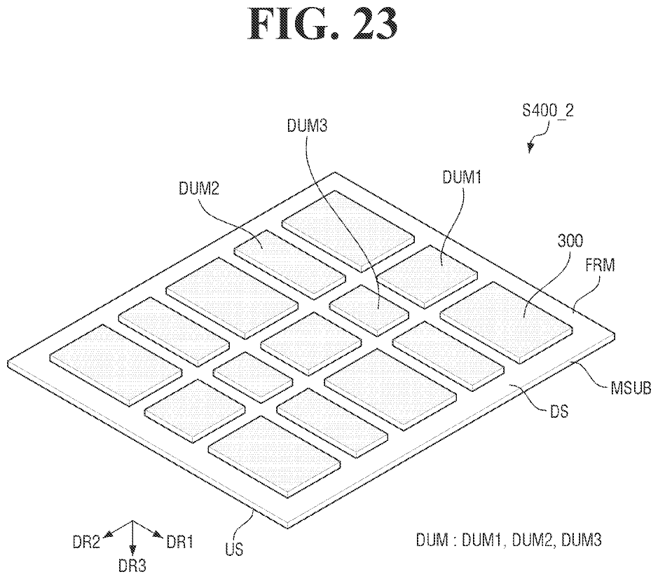

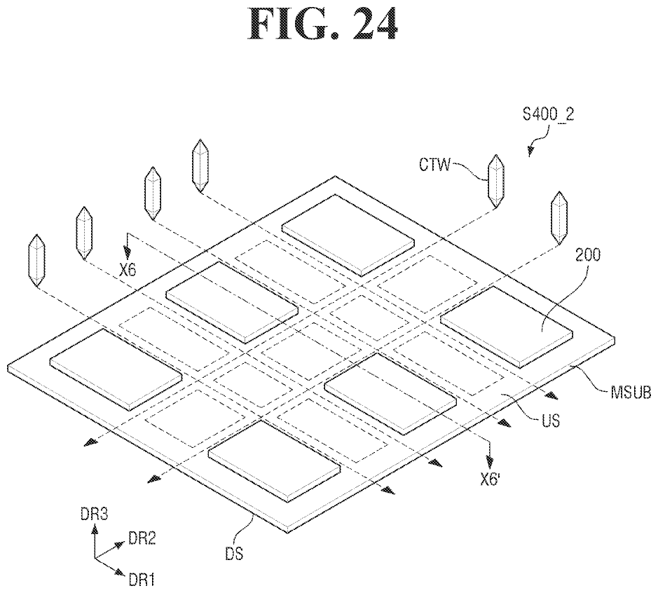

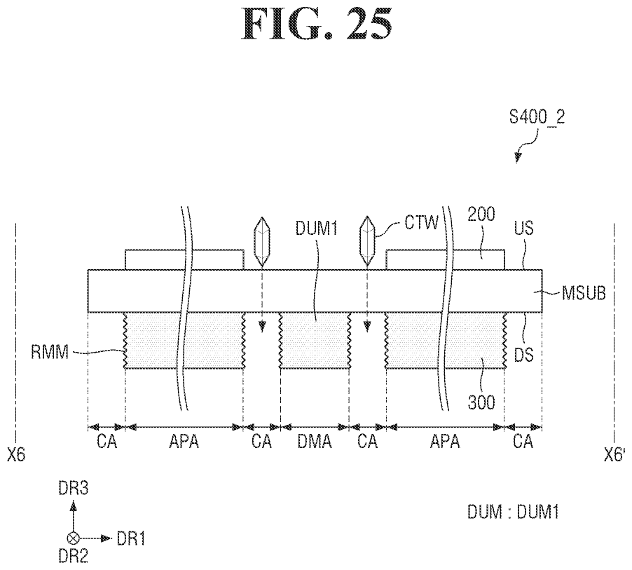

FIG. 20 is a flowchart illustrating a method of manufacturing a display device according to some embodiments. FIG. 21 is a perspective view illustrating operation S300_2 of FIG. 20. FIG. 22 is a cross-sectional view taken along line X5-X5′ of FIG. 21. FIG. 23 is a perspective view illustrating operation S400_2 of FIG. 20. FIG. 24 is a perspective view illustrating operation S400_2 of FIG. 20. FIG. 25 is a cross-sectional view taken along line X6-X6′ of FIG. 24.

In FIG. 23, the third direction DR3 in which an upper surface US of a mother substrate MSUB faces is downward, and the opposite direction in which a lower surface DS of the mother substrate MSUB faces is upward. In FIG. 24, the third direction DR3 in which the upper surface US of the mother substrate MSUB faces is upward, and the opposite direction in which the lower surface DS of the MSUB faces is downward.

Referring to FIGS. 20 through 24, the method S2 of manufacturing the display device according to the current embodiment is different from the method S1 of manufacturing the display device according to the embodiment described above with reference to FIG. 9, etc. in that dummies DUM are included.

For example, the method S2 of manufacturing the display device according to the embodiment may include forming display layers on one surface of a mother substrate (operation S100), forming a frame including openings and dummy openings by applying a first resin to the other surface of the mother substrate and curing the first resin (operation S200), forming protective members and dummies by applying a second resin to the openings and the dummy openings of the frame and curing the second resin (operation S300), and cutting the mother substrate from the one surface to the other surface after removing the frame (operation S400).

First, as illustrated in FIGS. 24 and 25, in the forming of the display layers on the one surface of the mother substrate (operation S100), display layers 200 may be formed on a surface, for example, the upper surface US of the mother substrate MSUB.

The display layers 200 may be located on the upper surface US of the mother substrate MSUB at regular intervals along the first direction DR1 and the second direction DR2. For example, the display layers 200 may be located in a matrix direction to form display cells, respectively. Here, as illustrated in FIG. 25, the display layers 200 may be spaced apart from each other with a dummy area DMA (where a dummy DUM to be described later is located) between them.

Next, as illustrated in FIGS. 21 and 22, in the forming of the frame including the openings and the dummy openings by applying the first resin to the other surface of the mother substrate and curing the first resin (operation S200), the mother substrate MSUB may further include dummy areas DMA.

Each of the dummy areas DMA is an area where a dummy DUM is located and may be an area overlapping the dummy DUM. The dummy areas DMA may be surrounded by a cutting area CA. The dummy areas DMA may include first dummy areas located between application areas APA in the first direction DR1, second dummy areas located between the application areas APA in the second direction DR2, and third dummy areas located between the second dummy areas in the first direction DR1 and/or between the first dummy areas in the second direction DR2.

A first resin RSN1 may be applied onto the cutting area CA except for the application areas APA and the dummy areas DMA.

A frame FRM formed by curing the first resin RSN1 may surround the application areas APA and the dummy areas DMA. The frame FRM may include openings OP overlapping the application areas APA and dummy openings DOP overlapping the dummy areas DMA. The dummy openings DOP may include first dummy openings DOP1 overlapping the first dummy areas, second dummy openings DOP2 overlapping the second dummy areas, and third dummy openings DOP3 overlapping the third dummy areas.

Next, in the forming of the protective members and the dummies by applying the second resin to the openings and the dummy openings of the frame and curing the second resin (operation S300), protective members 300 and dummies DUM may be formed by curing a second resin RSN2. The dummies DUM may be formed to have substantially the same thickness and the same material as the protective members 300 through the same process.

The dummies DUM may be located on the dummy areas DMA. The dummies DUM may be surrounded by the frame FRM located on the cutting area CA. The dummies DUM may be located in the dummy openings DOP of the frame FRM. The dummies DUM may include first dummies DUM1 located in the first dummy openings DOP1, second dummies DUM2 located in the second dummy openings DOP2, and third dummies DUM3 located in the third dummy openings DOP3. Each of the first dummies DUM1 may be located between the protective members 300 in the first direction DR1, each of the second dummies DUM2 may be located between the protective members 300 in the second direction DR2, and each of the third dummies DUM3 may be located between the second dummies DUM2 in the first direction DR1 or between the first dummies DUM1 in the second direction DR2.

Next, as illustrated in FIGS. 23 through 25, in the cutting of the mother substrate from the one surface to the other surface after removing the frame (operation S400), the frame FRM may be removed from the mother substrate MSUB. As described above, because the elongation rate of the frame FRM is high, the frame FRM can be easily removed without a residue on the mother substrate MSUB.

A cutting member CTW may cut the mother substrate MSUB. For example, the cutting member CTW may cut the mother substrate MSUB along the cutting area CA located between the first dummies DUM1 and the protective members 300, between the second dummies DUM2 and the protective members 300, between the first dummies DUM1 and the third dummies DUM3, and between the second dummies DUM2 and the third dummies DUM3.

In some embodiments, as illustrated in FIGS. 24 and 25, the cutting process may be performed from the upper surface US where the display layers 200 are located to the lower surface DS where the protective members 300 are located.

In the method S2 of manufacturing the display device according to some embodiments, because the dummies DUM are formed between the protective members 300, the mother substrate MSUB can be prevented from being locally bent by the pressure of the cutting member CTW during the cutting process. Accordingly, it is possible to prevent internal breakage or chipping defects of the mother substrate MSUB.

In concluding the detailed description, those skilled in the art will appreciate that many variations and modifications can be made to the disclosed embodiments without substantially departing from the principles of the invention. Therefore, the disclosed embodiments of the invention are used in a generic and descriptive sense only and not for purposes of limitation.

What is claimed is:

1. A method of manufacturing a display device, the method comprising:
forming a frame comprising openings by applying a first resin to a surface of a mother substrate and curing the first resin;
forming protective members by applying a second resin to the openings of the frame and curing the second resin; and
cutting the mother substrate along an area between the protective members after removing the frame,
wherein the second resin comprises a different material from the first resin.

2. The method of claim 1, wherein in the forming of the protective members, the protective members are surrounded by the frame and located in the openings.

3. The method of claim 1, wherein in the forming of the protective members, a thickness of the second resin before being cured in the openings is smaller than or equal to a thickness of the frame.

4. The method of claim 3, wherein a thickness of the second resin after being cured in the openings is in a range of 40% to 60% of the thickness of the second resin before being cured.

5. The method of claim 3, wherein a thickness of each protective member is in a range of 100 to 300 micrometers (μm).

6. The method of claim 1, wherein the second resin comprises at least at least one of a binder, first fillers, second fillers, light blocking materials, or foaming agents.

7. The method of claim 6, wherein
the first fillers comprise at least one of a carbon-based material or a ceramic-based material, and
the second fillers comprise at least one of a carbon-based material or a metal-based material.

8. The method of claim 6, wherein the light blocking materials comprise at least one of carbon black, black pigment, or black dye.

9. The method of claim 6, wherein the binder comprises at least one of acrylic resin, urethane resin, silicone resin, or rubber resin.

10. The method of claim 1, wherein an elongation rate of the frame is 200% or more.

11. The method of claim 1, wherein in the forming of the frame, the first resin is cured through thermal curing or natural curing.

12. The method of claim 1, wherein the second resin has a viscosity in a range of 10,000 to 50,000 centipoise (cPs).

13. The method of claim 1, wherein in the removing of the frame, the protective members comprise removal marks formed on side surfaces thereof as a result of removing the frame.

14. The method of claim 1, wherein
in the cutting of the mother substrate, a dummy is between the protective members, and
the mother substrate is cut along an area between the dummy and each of the protective members.

15. The method of claim 1, wherein in the forming of the protective members, the second resin is applied into the openings through a screen printing method using a blade.

16. The method of claim 1, further comprising forming display layers on the other surface located opposite the surface of the mother substrate.

17. A display device comprising:
a substrate;
a display layer on a first surface of the substrate; and
a protective member on a second surface of the substrate opposite the first surface and comprising a resin,
wherein
the protective member comprises removal marks on side surfaces thereof, and
the removal marks are formed as a result of removing a frame surrounding the protective member.

18. The display device of claim 17, wherein a thickness of the protective member is in a range of 100 to 300 micrometers (μm).

19. The display device of claim 17, wherein the resin comprises at least one of a binder, first fillers, second fillers, light blocking materials, or foaming agents.

20. The display device of claim 19, wherein
the first fillers comprise at least one of a carbon-based material or a ceramic-based material, and
the second fillers comprise at least one of a carbon-based material or a metal-based material.

21. The display device of claim 19, wherein the light blocking materials comprise at least one of carbon black, black pigment, or black dye.

22. The display device of claim 19, wherein the binder comprises at least one of acrylic resin, urethane resin, silicone resin, or rubber resin.

23. The display device of claim 17, wherein an elongation rate of the frame is 200% or more.
